(19) United States
(12) Patent Application Publication
(10) Pub. No.: US 2009/0278536 A1
(43) Pub. Date: Nov. 12, 2009

(54) WAVE-PROPAGATION BASED ESTIMATION OF COIL SENSITIVITIES

(75) Inventors: Richard Winkelmann, Hamburg (DE); Peter Boernert, Hamburg (DE)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/296,937

(22) PCT Filed: Mar. 16, 2007
(86) PCT No.: PCT/US07/64194

§ 371 Date: Oct. 13, 2008

Related U.S. Application Data
(60) Provisional application No. 60/744,755, filed on Apr. 13, 2006.

(51) Int. Cl. G01R 33/48; G06F 19/00; G01R 33/44

(52) U.S. Cl. 324/309; 702/66; 324/318

(57) ABSTRACT

Low resolution image data from a whole-body coil (18) and each coil element (20₁, 20₂, . . . 20ₙ) of a parallel imaging coil are received in a memory or buffer (34). A reconstruction processor (36) reconstructs the low resolution whole-body coil data and the low resolution data from each of the coil elements into corresponding low resolution images (38). The low resolution from each coil element is divided (42) by the low resolution image from the whole-body coil to generate a corresponding sensitivity map (44₁, 44₂, . . . 44ₙ) for each of the coil elements. In areas where the low resolution body coil image has near-zero values or in areas where the values in the body coil or receive coil images are changing very rapidly, the sensitivity maps have defects. A sensitivity map or correction circuit or algorithm (50) determines regions of the sensitivity maps which are defective and interpolates/extrapolates adjacent portions of the sensitivity maps in accordance with (a) a coil geometry map (56) and (b) a wave-propagation model (58) to correct the defective regions, to propagate them into the outer regions of the field of view or to fully replace the measured sensitivity map and create a corrected sensitivity map for each coil element.

The present application relates to parallel imaging techniques. It finds particular application in conjunction with medical diagnostic imaging using SENSE parallel imaging techniques and will be described with particular reference thereto. However, it is to be appreciated that the present application is also applicable to other parallel imaging techniques and imaging for other than medical diagnostic purposes.

Various parallel imaging techniques are known for generating magnetic resonance images more rapidly. These parallel imaging techniques include SENSE, SMASH, and others. During magnetic resonance imaging, different receive coils, or groups of receive coil(s), sample different portions of k-space concurrently. In reconstructing the diagnostic image, the data from each coil (or group) is transformed or “unfolded” in accordance with its sensitivity. Accuracy of the final image depends on accurately determining the coil sensitivities.

To obtain the sensitivity information, a low-resolution scan is performed that acquires image data for a large field-of-view for each receive coil element as well as for the whole-body receive coil. The single coil images are each divided by the body coil image, which serves as a reference. The result of this division can be regarded as the sensitivity map of the corresponding receive coil element or group of co-acting elements. Accuracy of the final image is dependent on accuracy in the sensitivity maps. Errors in the determined sensitivities can lead to so-called “SENSE-artifacts” attributable to incomplete unfolding of the image and remaining signal parts persisting and appearing as an image artifact. This problem becomes more pronounced as the SENSE acceleration factor, i.e., the degree of sub-sampling k-space increases.

One problem that can lead to sensitivity inaccuracies is attributable to regions of low signal density. In these low signal density regions, the signal in the reference scan is noisy, which leads to an unstable or inaccurate coil sensitivity estimation. Another cause for inaccuracy is attributable to the low resolution of the reference scan. In principle, the coil sensitivity map is a spatially smooth function inside the field-of-view, which can be accurately sampled by a low resolution voxel size of a few cubic centimeters. However, close to the coil element, the coil sensitivity rises steeply. When the receive coil is a surface coil that is positioned on or very close to the patient, the low-resolution reference scan is not sufficient to project sensitivities accurately in the area of steep increase close to the coil.

One technique for addressing the regions of low signal level is to average the signal several times to improve the signal-to-noise ratio. However, signal artifacts during the scan can dominate the signal content. In regions with physiological movement, the averaged images may not be accurately aligned in all regions. For example, in the pulmonary region, cardiac motion and blood flow creates ghost and smearing artifacts. Linear or other mathematical interpolation methods have been proposed to correct coil sensitivities in low-signal areas. They can also perform extrapolation to a certain extent. However, because such interpolation techniques do not take the coil geometry into account, they also suffer inaccuracies in both inter- or extrapolated low-signal areas as well as for high sensitivity regions near the coil.

The present application provides overcomes these and other problems by applying electromagnetic restraints to applied interpolation or extrapolation techniques.

In accordance with one aspect, a diagnostic imaging system is provided. An interpolator receives sensitivity maps for each of a plurality of parallel imaging coil elements. The sensitivity maps have defects in identifiable regions. The interpolator interpolates data from each sensitivity map, or the underlying data from which it is generated, in accordance with (a) a pre-loaded coil geometry and (b) a wave-propagation model to correct the defective regions to create a sensitivity map for each coil element or to fully predict it by (b) for the entire field of view.

Sensitivity maps are received in regions were no information was available because of:
low signal intensity
patient motion between or during reference scan and actual SENSE scan.

One advantage resides in more accurate unfolding in parallel imaging techniques.

Another advantage resides in reducing SENSE-artifacts and improved coil signal combination in non-accelerated scans

Another advantage resides in facilitating imaging with a large number of parallel imaging channels.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

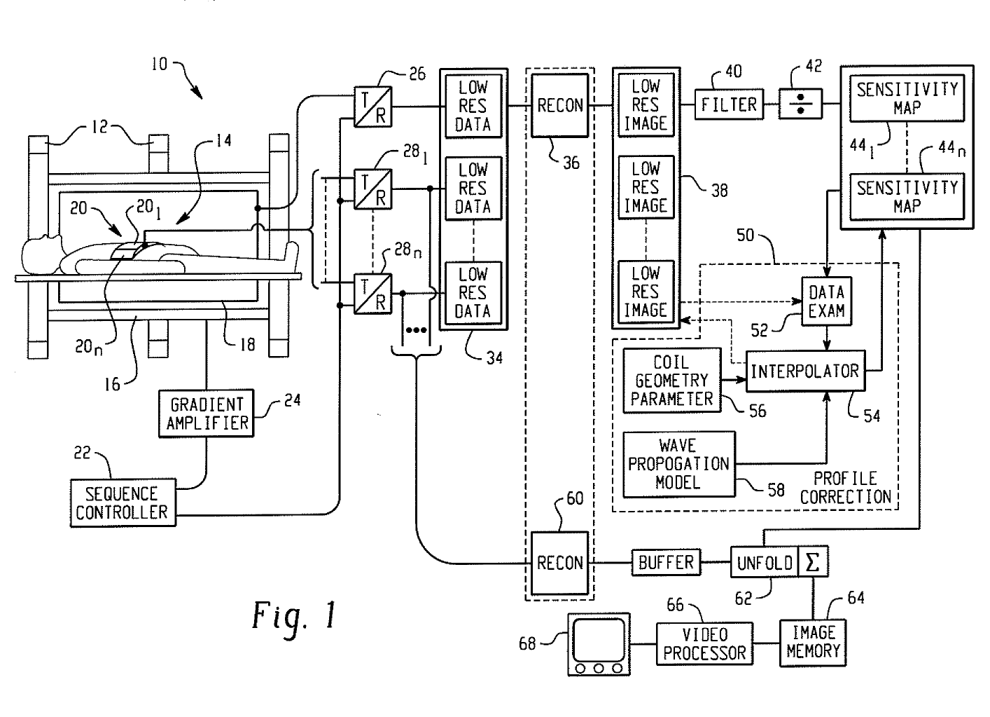

FIG. 1 is a diagrammatic illustration of a magnetic resonance imaging system in accordance with the present invention;

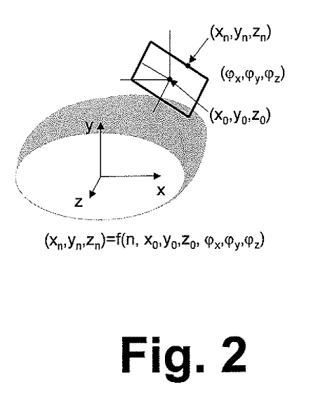

FIG. 2 illustrates a relationship between coil geometry and current and spatial coordinates;

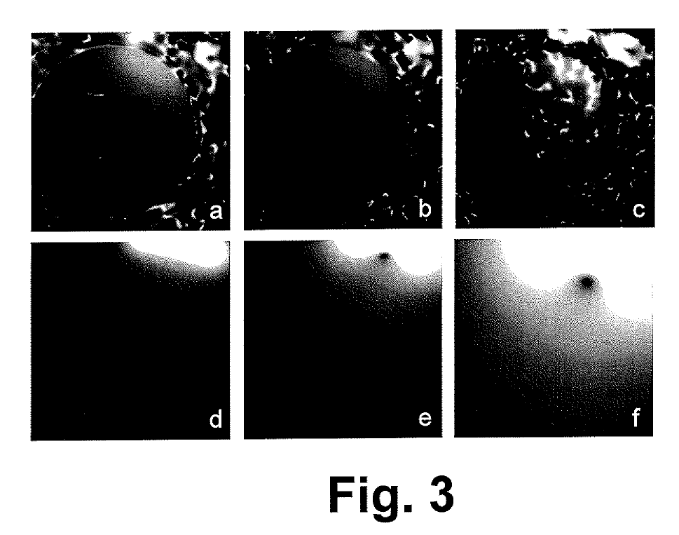

FIGS. 3a, 3b, and 3c represent “gold standard” sensitivities for a slice at offsets of Δz=0 mm, Δz=10 mm, and Δz=40 mm, respectively;

FIGS. 3d, 3e, and 3f illustrate sensitivities obtained at phantom offsets of Δz=0 mm, Δz=10 mm, and Δz=40 mm, respectively, using the wave-propagation based sensitivity estimation approach described in this application;

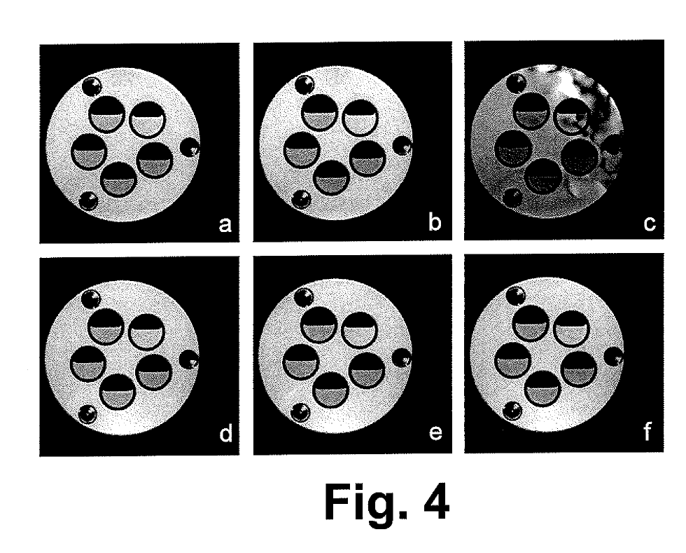

FIGS. 4a, 4b, and 4c are reconstructions of the phantom offsets of 0, 10, and 40 millimeters, respectively, in which the sensitivity maps are generated by dividing the low-resolution coil images by the low-resolution whole body coil image without the presently described wave-propagation sensitivity interpolations; and,

FIGS. 4d, 4e, and 4f are reconstructions of the same phantom with 0, 10, and 40 millimeters shifts, respectively, using the presently described interpolation with wave-propagation electromagnetic restraints.

With reference to FIG. 1, an MRI imaging system 10 includes a main field coil or coils 12 which generate a main or B₀ magnetic field through an imaging region 14. The main field coils can be superconducting, resistive, permanent magnets, or the like. A gradient coil 16 applies gradient magnetic fields Gₓ, G_{y}, G_{z}, across the B₀ field to provide spatial, frequency, and phase-encoding. A whole-body transmit/receive coil 18 transmits resonance excitation and manipulation RF pulses into the imaging region 14 and receives magnetic resonance signals from the imaging region.

A local parallel imaging coil 20 is disposed adjacent the subject in the imaging region 14. The parallel imaging coil includes a plurality of elements or loops which function independently or in small groups, hereinafter coil elements 20₁, 20₂, . . . 20ₙ to generate imaging data from different sub-regions of k-space concurrently.

A sequence controller 22 controls gradient amplifiers 24 for controlling the gradient coil to apply gradient field pulses and a transmitter/receiver (T/R) unit 26 for supplying the magnetic resonance excitation pulses to the whole-body coil 18. The sequence controller further controls a series of transmitter/receiver (T/R) units 28₁, 28₂, . . . 28ₙ for controlling a plurality of n T/R units, each associated with one of n independently drivable coil elements of the parallel imaging RF coil 20. The sequence controller 22, during initial set-up calibration with a subject, among other operations, controls the gradient amplifiers, the whole-body coil T/R unit 26, and the parallel-imaging T/R units 28₁, 28₂, . . . 28ₙ to execute a low-resolution imaging sequence to acquire the data to generate a sensitivity map. After set-up is complete, the sequence controller further controls the amplifier and transmitters to perform any of a plurality of magnetic resonance imaging sequences.

During the generation of the sensitivity map, the T/R unit 26 receives and demodulates the resonance signals from the whole-body coil 18. The T/R units 28₁, 28₂, . . . 28ₙ receive and demodulate the resonance signals from each independent coil element of the parallel imaging coil 20. The received resonance signals are downloaded into individual buffers or appropriate portions of a imaging data memory 34. A reconstruction processor or processors 36 reconstruct the low resolution image data into a corresponding series of low resolution images which are stored in individual or corresponding sections of an image memory 38. A smoothing function 40 smooths the images. A divider 42 divides, on a pixel-by-pixel basis, the low resolution image from each coil element of the parallel imaging coil 20 by the whole-body image to generate a corresponding sensitivity map 44₁, 44₂, . . . 44ₙ for the n coil elements which are stored in appropriate portions of a sensitivity map memory 46. These thus generated sensitivity maps are also called the “gold standard” maps in the following.

A sensitivity map correction circuit or algorithm 50 includes an algorithm or processor 52 which examines the low-resolution images or data to determine regions in which the signal-to-noise ratio is unacceptably low or the rate of sensitivity gradient change is above a preselected rate. For each identified region, an interpolator 54 interpolates the sensitivity or image values from neighboring voxels or pixels in an acceptable signal-to-noise or rate-of-change region in accordance with coil geometry parameters of the corresponding coil from a geometric parameter memory 56 which is preloaded with the coil configuration and current characteristics of the whole-body coil and each of the independent coil elements of the parallel imaging coil 20. The interpolator also interpolates the coil sensitivities in accordance with the Maxwell's Equations or other wave-propagation model from a wave model memory 58. The results of this geometric parameter and Maxwell's Equations-based interpolation and extrapolation with electromagnetic restraints are returned to the low resonance image memory 38 to replace the corresponding low signal-to-noise or rapidly changing sensitivity gradient regions of the images with the interpolated values. Alternately, the interpolated regions can be ratioed and substituted directly in the sensitivity maps, or the complete sensitivity map can be fully replaced by the wave-propagation results. As yet another alternative, as explained in greater detail below, geometry and wave-propagation-based sensitivities and the original sensitivities are fit or melded together. Details of the inter-/extrapolation are set forth below. As a further refinement, the sensitivity maps can be adjusted to reflect coil element coupling. The corrected sensitivity maps could be generated by defining a set of basis functions to describe a general coil sensitivity that is adjusted on a patient-by-patient basis.

During a parallel imaging sequence, the data received from each coil element of the parallel imaging coil 20 are reconstructed with a reconstruction processor or computer algorithm 60 (which can be the same as 36) to generate corresponding high resolution sub-images, an unfolding processor 62 unfolds or transforms the sub-image from each coil element with the corresponding corrected coil sensitivity map from the coil sensitivity map memory 44 and summed to generate an image which is stored in an image memory 64. This technique is also advantageous for moving table imaging techniques, as well as for simple coil signal combination if no parallel imaging acceleration is performed. A video processor 66 selects portions of the reconstructed image or images, performs post-processing enhancements, and the like, and controls the generation of displays on a monitor 68 or other human-readable display. The video processor further controls the transfer of reconstructed images to a patient-record database for future retrieval.

In general, all image content that is different for different receive coils is related to its coil sensitivity, which is a complex function. The underlying anatomical information, also complex, is identical for all receive coils as well as for the body coil. This means that the coil sensitivity is independent of the anatomical information, but it may be influenced by the patient in a more general way.

The signal in a voxel in the spatial domain acquired by a coil element i includes the contributions:

Cᵢ=SᵢT_{QBC}ρ (1),

where Cᵢ represents the total signal of coil element i, Sᵢ the corresponding sensitivity at the voxel's position, and T_{QBC} combines all influence introduced by the RF transmission of the quadrature body coil 18. The underlying anatomical information is specified by the voxel density ρ. To separate these different components, the same scan is acquired nearly simultaneously using the body coil 18 for signal reception. To obtain the coil sensitivity, the signal Cᵢ is divided by the body coil signal C_{QBC} in the divider circuit or algorithm 42:

$${\tilde{S}}_{i} = \frac{{c}_{i}}{{c}_{QBC}} , with {c}_{QBC} = {S}_{QBC} {T}_{QBC} ρ , \qquad ( 2 )$$

which leads to:

$${\tilde{S}}_{i} = \frac{{S}_{i }}{{S}_{QBC}} . \qquad ( 3 )$$

This means that the applied coil sensitivities \tilde{S}ᵢ are weighted by the inverse of the body coil sensitivity. This is in general, not critical, because the sensitivity of the body coil can be considered to be constant in both magnitude and phase, which allows for artifact-free SENSE reconstruction. As set forth above, the coil sensitivities are, in general, smooth functions, which require only a low resolution for the preferred reference scan. Spatial smoothing of both the single coil images and the whole-body coil reference image can be performed by the cos² filter 40 which is applied before the division operation. This can be further stabilized by regulation. Sensitivity maps generated by dividing the low-resolution image from each coil element by the low-resolution image from the whole-body coil are referred to as the “gold standard” sensitivity.

The coil sensitivities can also be described in a more theoretical and general way. It is a property of a receive coil element, how sensitive it is at a specific spatial position. Using the reciprocity theorem, the sensitivity of a receive coil is proportional to its transverse H-fields generated by a unit current in the coil element:

S_{coil}≈Hₓ+jH_{y} (4).

These transverse fields are dependent on coil geometry, as well as the wave propagation in a specified media, in this case the subject's body. For simplicity, the magnetic field can be described by a rotation vector of a vector potential \vec{A}:

$$\vec{H} = \frac{1}{μ} rot \vec{A} , \qquad ( 5 )$$

This vector potential \vec{A} is provoked by the source of the magnetic field, the current density in the conductor of the coil. Assuming an infinitesimal width and height of the conductor, this density can be defined as a complex current I along the conductor position \vec{r}₀:

$$\vec{A} ( \vec{r} ) = {∮}_{{\vec{r}}_{0}}^{ } μ \frac{\underline{I} ( {\vec{r}}_{0} ) d {\vec{r}}_{0}}{4 π} \frac{1}{\vert \vec{r} - {\vec{r}}_{0} \vert} {e}^{j ( ϖ t - k \vert \vec{r} - {\vec{r}}_{0} \vert )} \qquad ( 6 )$$

where \vec{r} represents the point in the field-of-view at which the field is calculated. This means that the contributions of the vector potential are integrated along the coil conductor. To allow a numeric calculation, the integral along the conductor loop is decomposed into several short electric dipoles n, whose contributions sum to \vec{A}:

$$\vec{A} ( \vec{r} ) = {\sum }_{n} μ \frac{\underline{I} ( {\vec{r}}_{0 , n} ) Δ {\vec{l}}_{n}}{4 π} \frac{1}{\vert \vec{r} - {\vec{r}}_{0 , n} \vert} {e}^{j ( ϖ t - k \vert \vec{r} - {\vec{r}}_{0 , n} \vert )} \qquad ( 7 )$$

Consequently, the transverse components of the magnetic field H in Equation (5) can be written in a Cartesian coordinate scheme as:

$$\begin{matrix}\begin{matrix}{H}_{x} = \frac{1}{μ} ( \frac{\partial {A}_{z}}{\partial y} - \frac{\partial {A}_{y}}{\partial z} ) \\ = \frac{1}{μ} ( \frac{\partial {A}_{z}}{\partial r} \frac{\partial r}{\partial y} - \frac{\partial {A}_{y}}{\partial r} \frac{\partial r}{\partial z} ) ,\end{matrix} & ( 8 ) \\ \begin{matrix}{H}_{y} = \frac{1}{μ} ( \frac{\partial {A}_{x}}{\partial z} - \frac{\partial {A}_{z}}{\partial x} ) \\ = \frac{1}{μ} ( \frac{\partial {A}_{x}}{\partial r} \frac{\partial r}{\partial z} - \frac{\partial {A}_{z}}{\partial r} \frac{\partial r}{\partial x} ) .\end{matrix} & ( 9 )\end{matrix}$$

Together with Equation (7), this leads to the final expressions for the complex sensitivity components:

$$\begin{matrix}\underline{{H}_{x}} = {\sum }_{n} \{ \begin{matrix}- \frac{\underline{I} ( {\vec{r}}_{0 , n} ) Δ {z}_{n}}{4 π} \frac{y - {y}_{0 , n}}{{r}_{n}} ( \frac{j \underline{k}}{{r}_{n}} + \frac{1}{{r}_{n}^{2}} ) {e}^{j ( ω t - \underline{k} {r}_{n} )} + \\ \frac{\underline{I} ( {\vec{r}}_{0 , n} ) Δ {y}_{n}}{4 π} \frac{z - {z}_{0 , n}}{{r}_{n}} ( \frac{j \underline{k}}{{r}_{n}} + \frac{1}{{r}_{n}} ) {e}^{j ( ω t - \underline{k} {r}_{n} )}\end{matrix} \} , & ( 10 ) \\ \underline{{H}_{y}} = {\sum }_{n} \{ \begin{matrix}- \frac{\underline{I} ( {\vec{r}}_{0 , n} ) Δ {x}_{n}}{4 π} \frac{z - {z}_{0 , n}}{{r}_{n}} ( \frac{j \underline{k}}{{r}_{n}} + \frac{1}{{r}_{n}^{2}} ) {e}^{j ( ω t - \underline{k} {r}_{n} )} + \\ \frac{\underline{I} ( {\vec{r}}_{0 , n} ) Δ {z}_{n}}{4 π} \frac{x - {x}_{0 , n}}{{r}_{n}} ( \frac{j \underline{k}}{{r}_{n}} + \frac{1}{{r}_{n}^{2}} ) {e}^{j ( ω t - \underline{k} {r}_{n} )}\end{matrix} \} , & ( 11 )\end{matrix}$$

where rₙ=\sqrt{(x−x_{0,n})²+(y−y_{0,n})²+(z−z_{0,n})²},
the length Δ\vec{l} of the electrical dipole n decomposed into Δxₙ, Δyₙ, Δzₙ. It should be noted that the wave number k is of complex nature. These general equations are used in the following to estimate the coil sensitivities. Using a numerical optimization technique (e.g. simplex algorithm), the free parameters given in the model discussed by Eq. 13 (resp. 11-12) are fitted to the measured coil sensitivities. An appropriate penalty function compares the forward calculated field using this model with the gold standard sensitivities at several interpolation points. Minimizing the variants of these interpolation points by adjusting several parameters like coil position and loading, an accurate sensitivity estimation can be found. A system-wide inter- and extrapolated coil sensitivity map could be generated. Analogously, for a symmetric coil with a rigid array, coil sensitivity map calculation might be simplified.

Equations (4), (10), and (11) define the coil sensitivity of a receive coil element based on its shape and geometric set-up, but also as influenced by object properties of the human body. The complex wave number k contains propagation properties which depend on the wave propagation path in the human body. More specifically, the conductivity σ and the permittivity ε are covered by the correlation:

k²=εμω²−jσμω (12).

The variation of the permeability μ of less than 10⁻⁵ in the human body is negligible with respect to wave propagation and can be replaced by μ₀. ω, representing the rotating frame frequency, is a known quantity and can be considered a constant. Consequently, the properties for the human body are taken into account in a global way by the complex wave number k. However, more complex models are conceivable. For the human body, the complex wave number k, based on the wave propagation number for water, can be used as starting value in the numerical optimization routine.

Regarded as a global scaling parameter, the complex current induced in a receive coil element can be eliminated. The model defined current flows in a conductor of infinitesimal small width. Considering the current to be constant along the small conductor is an approximation which reduces the number of unknowns to one complex parameter I₀. Especially for small coil elements, this condition is well-defined, where and phase of the coil current will be constant along a small receive loop. For larger coils, an improved current distribution model may be more accurate.

With reference to FIG. 2, the shape of each coil element layout (a relative position of the dipoles to each other), is known from a priori knowledge. The coordinates (xₙ, yₙ, zₙ) of its current carrying conductor is described by three translation and three rotation parameters: center of mass x₀, y₀, z₀ and angulation (φₓ, φ_{y}, φ_{z}.

The geometric arrangement of the receive coil elements stored in memory 56 has a dominant influence on the coil sensitivity distribution. When the parallel imaging RF coil 20 is built-in or fixedly positioned at a known position in the bore, the sensitivity estimation is straight forward and the calculation effort is significantly reduced. However, with a coil that is freely positionable, the sensitivity distribution is still determinable.

For each element separately, the parameters of FIG. 2 are optimized:
(a) the absolute position of its center point is described by x₀, y₀, z₀;
(b) its rotation is defined along the three axes φₓ, φ_{y}, φ_{z}.
   This denotes a rigid geometry approach for each coil element of the parallel imaging coil 20. While its shape is known, its position and orientation is estimated by the parameters (a) and (b). Taking coil element interdependence of a rigid array into account can improve and simplify the parameter estimation procedure.

Summarizing, the parameters to be estimated for each coil element independently include six geometric parameters position and angulation (C₁-C₆), two parameters for the complex wave propagation number k representing global body properties (C₇, C₈), two global scaling parameters for the global amplitude and phase of the coil sensitivity attributable to current I₀ (C₉, C₁₀), and two additional parameters (C₁₁, C₁₂) which decouple the different exponential distance terms. The last two parameters (C₁₁, C₁₂), not mentioned so far, provide better agreement with reference data as compared to theoretical Equations (4), (10), and (11). The parameters (C₁₁, C₁₂) appear to compensate for more localized effects. The actual parameterized Equation is implemented as follows:

$$\begin{matrix}{\underline{S}}_{coil} = ( x , y , z ) \\ = {\sum }_{n} {( {\underline{H}}_{x} + j {\underline{H}}_{y} )}_{( n )} \\ = ( {C}_{9} + j {C}_{10} ) \cdot {\sum }_{n} \frac{1}{{r}_{n}^{2}} ( 1 + \frac{( {C}_{11} + j {C}_{12} )}{{r}_{n}} ) {e}^{- j ( {C}_{7} + j {C}_{8} ) r} \\ ( \begin{matrix}\begin{matrix}Δ {z}_{n} ( y - {y}_{n} ) + \\ Δ {y}_{n} ( z - {z}_{n} ) +\end{matrix} \\ Δ {x}_{n} ( z - {z}_{n} ) + \\ Δ {z}_{n} ( x - {x}_{n} )\end{matrix} ) ,\end{matrix} \qquad ( 13 )$$

with (xₙ, yₙ, zₙ)=f(n, C₁, C₂, C₃, C₄, C₅, C₆). f is dependent on the shape of the receive coil element.

In one embodiment, the above-discussed gold standard model and the above-discussed wave propagation approach are combined in the optimization process. The gold standard sensitivities can be inadequate in certain areas. Primarily, this problem is related to a low signal of the body coil, while areas of high body coil signal show stable and accurate sensitivity estimation. Consequently, points in the low-resolution reference scan with a high signal level are used as interpolation points for the sensitivity estimation.

The sensitivity estimates are calculated at these interpolation points using the wave propagation approach. The parameters described above are adjusted using an appropriate optimization strategy the simplex method to minimize the variants between the measured sensitivities and the estimated sensitivities.

As for any optimization, the starting values are important. If previously unknown, the starting values for the coil position are described by the maximum interpolation point of each receive coil element. The starting values for the angulation are derived from the general coil placement, which could be application dependent. Finally, estimates are used as starting points for scaling and loading parameters (e.g., εᵣ=10, σ=0.4 S/m).

The gold standard method is used to obtain the reference values at the interpolation points. The low resolution image of a receive coil element is divided 42 by the body coil reference. Using only voxels with high body coil signal, only stable values are used as the interpolation points. The resultant coil sensitivity estimation is calculated.

To generate the images shown in FIG. 3, two 110 mm in diameter loop coils were fixed to the scanner on top of a phantom and a third coil was positioned below the phantom. After the reference scan, three identical high-resolution volumes were acquired at table offsets of 0, 10, and 40 millimeters in the head direction. These offsets were achieved by displacing the table these corresponding distances. To reconstruct these volumes, the receive sensitivity for coil element was shifted together with the phantom, while the receive sensitivities of the first and second coils remained fixed. The sensitivity of the second coil element, which is fixed to the scanner, is shown at the three different positions in FIG. 3. FIGS. 3a-3c demonstrate the gold standard coil sensitivities; and FIGS. 3d-3f illustrate the sensitivities estimated by the wave propagation model. The problem described above for the gold standard sensitivities can best be seen FIG. 3c, which shows a very unstable coil sensitivity. This can be explained from the offset position of the slice. During the reference scan, only a very low signal was received a the position Δz=40 mm, which lead to this unstable sensitivity definition.

The model-based estimated sensitivity shown in FIGS. 3d-3f is able to generate a stable sensitivity at every position, even outside the phantom. It might be noted that the dark dot seen in FIGS. 3e and 3f has a real physical background. In a region close to the coil element, this coil is not sensitive to transverse magnetization, which results in a sensitivity close to zero. This point can also be seen in a single coil image, but is usually compensated by a neighboring element, which makes it invisible in the final reconstructed image.

The reconstructions of the corresponding slice acquired with the different offsets are shown in FIG. 4. The gold standard sensitivities were used for the reconstruction shown in FIGS. 4a-4c. The corresponding reconstructions applying the estimated sensitivities are shown in FIGS. 4d-4f A small offset between reference scan and SENSE accelerated scan can still be compensated by the gold standard approach shown in FIG. 4b. However, the missing information in holes of the reference scan does not allow a larger offset between the reference scan and the image scan, which leads to the serious reconstruction artifacts of FIG. 4c. Covering the complete area with an estimated coil sensitivity, the problem does not exist in FIG. 4f, which allows a high quality image reconstruction regardless of patient table motion.

The above-described processes can be performed with various circuits, components, processor algorithms, computer programs which are stored on disks or other electronic recording medium, and the like, all collectively denoted as computer programmable media.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A diagnostic imaging system for imaging a region of interest in a field of view, the system comprising:
an interpolator which receives sensitivity maps for each of a plurality of parallel imaging coil elements, which sensitivity maps have defects in identifiable regions, the interpolator interpolating/extrapolating data from each sensitivity map or underlying data from which it is generated in accordance with (a) a coil geometry and (b) a wave propagation model to correct the defective regions or to propagate the sensitivity into outer regions of the field of view to create a corrected sensitivity map for each coil element.

2. The imaging system according to claim 1, further including:
a memory or memory portion which receives low resolution image data from a whole body coil;
memories or memory portions which receive low resolution image data from each of the coil elements;
a reconstruction processor or algorithm which reconstructs the low resolution whole-body coil data into a low resolution whole body coil image representation and reconstructs the low resolution data from each of the coil elements into a corresponding low resolution image representation for each coil element;
a divider which divides the low resolution coil element images by the low-resolution whole-body coil low resolution image to generate the defected sensitivity maps, one defected sensitivity map corresponding to each coil element.

3. The imaging system according to claim 2, further including:
a reconstruction processor or algorithm which receives high-resolution data from each coil element, the high resolution data from each coil element representing a differing sub-region of k-space reconstructs the high-resolution data for each element into a corresponding partial image; and
an unfolding processor or algorithm which unfolds each partial image in accordance with the corresponding corrected sensitivity map, and sums the unfolded partial images into a high-resolution image representation.

4. The imaging system according to claim 3, further including:
a main magnet for generating a main magnetic field B₀ in an examination region;
a gradient field coil for creating gradient fields across the main magnetic field B₀;
a whole-body radio frequency coil for generating at least the whole body coil low-resolution image data; and,
a parallel imaging coil having a plurality of coil elements, each of which generates corresponding low-resolution data and corresponding high-resolution data.

5. The imaging system according to claim 1, further including:
a main magnet for generating a main magnetic field B₀ in an examination region;
a gradient field coil for creating gradient magnetic fields across the main magnetic field B₀;
a whole-body radio frequency coil for generating at least the whole body coil low-resolution image data; and,
a parallel imaging coil having a plurality of coil elements, each of which generates corresponding low-resolution image data and corresponding high-resolution image data representing different sub-regions of k-space.

6. The imaging system according to claim 5, further including:
a processor or algorithm which receives high-resolution data from each coil element, reconstructs the high-resolution data for each element into a corresponding partial image, unfolds each partial image in accordance with the corrected sensitivity map for the corresponding coil element, and sums the unfolded partial images into a high-resolution image representation.

7. The apparatus according to claim 1, wherein the wave propagation model is based on the Maxwell's Equations for wave propagation in homogeneous tissue.

8. The imaging system according to claim 1, wherein the interpolator performs a least fit analysis between the defected sensitivity maps and a sensitivity map generated based on the wave propagation model and the coil geometry map.

9. A diagnostic imaging system comprising:
means for receiving sensitivity maps for each of a plurality of imaging coil elements, which sensitivity maps have defects in identifiable regions;
means for interpolating/extrapolating data from each sensitivity map or underlying data from which it is generated in accordance with a coil geometry and a wave propagation model to correct the defective regions to create a corrected sensitivity map for each coil element.

10. A diagnostic imaging method comprising:
receiving sensitivity maps for each of a plurality of imaging coil elements, which sensitivity maps have defects in identifiable regions;
interpolating/extrapolating data from each sensitivity map or underlying data from which it is generated in accordance with a coil geometry and a wave propagation model to correct the defective regions to create a corrected sensitivity map for each coil element.

11. The method according to claim 10, wherein the interpolating/extrapolating includes propagating sensitivity data in accordance with the wave propagation model into peripheral regions of a field of view.

12. The method according to claim 10, further including:
receiving low resolution image data from a whole-body coil;
receiving low resolution image data from each of the coil elements;
reconstructing the low resolution whole-body coil data into a low resolution whole-body coil image representation;
reconstructing the low resolution data from each of the coil elements into a corresponding low resolution image representation for each coil element,
dividing the low resolution coil element images by the low resolution whole-body coil image to generate the defective sensitivity maps, one defective sensitivity map corresponding to each coil element.

13. The method according to claim 10, further including:
reconstructing high resolution data from each coil element into a corresponding partial image;
unfolding each partial image with the corresponding corrected sensitivity map; and,
combining the unfolded partial images into a high resolution image representation.

14. The method according to claim 13, further including:
generating a main magnetic field B₀ in an examination region;
creating gradient fields across the main magnetic field;
generating the whole-body low resolution image data; and,
generating the low resolution data and the high resolution data, the data from each parallel imaging coil element representing a different sub-region of k-space.

15. The method according to claim 10, further including:
generating a main magnetic field B₀ in an examination region;
creating gradient magnetic fields across the main magnetic field in the examination region;
generating the whole-body coil low resolution image data with a whole-body coil;
generating the low resolution image data from a plurality of coil elements; and
generating high resolution image data with the plurality of coil elements, the high resolution image data from each coil element representing a differing sub-region of k-space.

16. The method according to claim 15, further including:
reconstructing the high resolution data for each element into a corresponding partial image;
unfolding each partial image in accordance with the corrected sensitivity map for the corresponding coil element; and,
combining the unfolded partial images into a high resolution image representation.

17. The method according to claim 10, wherein the wave-propagation model is based on the Maxwell's Equations.

18. The method according to claim 10, wherein the defective sensitivity maps are each fit with a sensitivity map corresponding to each coil element based on the wave propagation model and the coil sensitivity map.

19. The method according to claim 10, wherein the defective regions of the sensitivity maps correspond to regions in which either a signal strength in low resolution image data from which the sensitivity map was generated is very low or values of the underlying data from which it is generated are changing rapidly.

20. A computer medium programmed to perform the method of claim 10.

21. A diagnostic imaging method comprising:
propagating a wave propagation sensitivity map in accordance with coil geometry and a wave propagation model;
generating a defected sensitivity map from low resolution image data;
reconciling the wave propagation sensitivity map and the defected sensitivity map to generate a corrected sensitivity map.
